(19) United States
(12) Patent Application Publication
(10) Pub. No.: US 2010/0073000 A1
(43) Pub. Date: Mar. 25, 2010

(54) RADIO FREQUENCY COIL APPARATUS AND METHODS

(75) Inventors: Reinhold Ludwig, Paxton, MA (US); Gene Bogdanov, Manchester, CT (US); Rostislav Lemdiasov, Worcester, MA (US); Peter Serano, Ashland, MA (US); Steven Toddes, Framingham, MA (US)

Correspondence Address: WOLF GREENFIELD & SACKS, P.C., 600 ATLANTIC AVENUE, BOSTON, MA, 02210-2206, US

(73) Assignee: Insight Neuroimaging Systems, LLC, Worcester, MA (US)

(21) Appl. No.: 12/235,228

(22) Filed: Sep. 22, 2008

(51) Int. Cl. G01R 33/341

(52) U.S. Cl. 324/318

(57) ABSTRACT

Radio frequency (RF) coil configurations and methods are disclosed. Non-magnetic elements may be used in combination with an RF coil. The non-magnetic elements may be metal. The non-magnetic metal elements may be designed and configured to facilitate tuning of an RF coil, and to modify a magnetic field produced by an RF coil. The non-magnetic metal elements may also be used in connection with a RF receiver coil to control the region from which the receiver coil detects signals. The configurations and methods described may be used in various RF applications, including magnetic resonance imaging (MRI).

### BACKGROUND

1. Field

The technology described herein relates to radio frequency coils, and methods of using the same in various contexts, such as in magnetic resonance imaging (MRI) applications.

2. Discussion of Related Art

Radio frequency (RF) coils are used in magnetic resonance imaging (MRI). In that context, the RF coils are typically designed for operation at 63 MegaHertz (MHz) to 500 MHz. These RF coils generate magnetic fields to excite an area of a biological test subject, such as part of an animal's or human's anatomy. RF coils are also used to detect RF signals from the test subject in response to the excitation magnetic fields. Some RF coils are operated only as transmitters. Some are operated only as receivers. Some are operated as combined transmitters and receivers, thus performing both the function of generating an excitation magnetic field as well as detecting an RF response of the test subject.

### BRIEF SUMMARY

According to one aspect, an apparatus is provided, comprising a radio frequency (RF) coil, and a non-magnetic metal element electromagnetically coupable to the RF coil to do at least one of form a resonant system with the RF coil, focus a magnetic field produced by the RF coil, and increase a sensitivity of detection of the RF coil.

According to another aspect, an apparatus comprises a Helmholtz coil pair formed of a first radio frequency (RF) coil disposed in a first plane and a second RF coil disposed in a second plane substantially parallel to the first plane. The Helmholtz coil pair defines a central volume therebetween. The apparatus further comprises a non-magnetic metal element disposed outside the central volume and having a perimeter disposed in a third plane, the third plane substantially parallel to the first and second planes.

According to another aspect, an apparatus is provided comprising a Helmholtz coil pair formed of a first radio frequency (RF) coil and a second RF coil. The apparatus further comprises a non-magnetic metal element electromagnetically coupable to the first RF coil and/or the second RF coil to do at least one of form a resonant system with the first RF coil and/or the second RF coil, control an area of uniform magnetic field between the first RF coil and the second RF coil, and increase a sensitivity of detection of the first RF coil and/or the second RF coil.

According to another aspect, a method comprises electromagnetically coupling a non-magnetic element to a radio frequency (RF) coil to create a resonant system comprising the RF coil and the non-magnetic element.

According to another aspect, a method of producing a magnetic field using a radio frequency (RF) coil having a first side and a second side is disclosed. The method comprises exciting an RF coil having a non-magnetic metal element proximate a first side of the RF coil by providing an RF input signal to the RF coil, thereby generating the magnetic field on the second side of the RF coil.

According to another aspect, a method of defining a detection region of a radio frequency (RF) coil is disclosed. The RF coil has a first side and a second side. The method comprises electromagnetically coupling a non-magnetic metal element proximate the first side of the RF coil to the RF coil to increase a sensitivity of detection of the RF coil to electromagnetic fields on the second side of the RF coil.

### BRIEF DESCRIPTION OF THE DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1A is an RF coil configuration utilizing non-magnetic elements, according to one embodiment;

FIG. 1B is alternative view of the coil configuration of FIG. 1A;

FIG. 1C is an end-on view of one of the RF coils and non-magnetic metal elements of FIGS. 1A-1B;

FIG. 2A is an exemplary implementation of the coil configuration of FIGS. 1A-1B;

FIG. 2B is a detailed view of a portion of FIG. 2A, showing the interconnection of the two RF coils of FIG. 2A;

FIGS. 3A-3C are graphs illustrating various characteristics of the coil configuration of FIG. 2A;

FIG. 4 illustrates a simulated magnetic field map for an RF coil configuration of the type illustrated in FIGS. 1A-1B;

FIGS. 5A-5B illustrate an RF coil configuration utilizing concave non-magnetic metal elements in connection with two RF coils;

FIG. 6 illustrates a simulated magnetic field map for an RF coil configuration of the type illustrated in FIGS. 5A-5B;

FIGS. 7A-7B illustrate alternative views of an exemplary combination of an RF coil and a segmented non-magnetic metal element;

FIG. 7C is an exemplary RF coil configuration formed of a pair of RF coils and non-magnetic metal elements like those illustrated in FIGS. 7A-7B;

FIG. 8 is a cross section of an RF coil and a non-magnetic metal element having an adjustable curvature and/or an adjustable spacing;

FIG. 9 illustrates an example of a segmented conductor having non-uniform segment lengths, which may be used to form an RF coil;

FIG. 10 is an RF coil configuration utilizing curved RF coils and curved non-magnetic elements; and

FIG. 11 illustrates a simplified diagram of an MRI apparatus including the RF coil configuration of FIGS. 1A-1B.

### DETAILED DESCRIPTION

For ease of understanding, and without limiting the scope of the various aspects, the RF coil apparatus and methodology is described in the context of MRI. In MRI applications, RF coils may be used to generate RF magnetic fields for exciting a test subject, and may also be used to detect the response of the test subject to the excitation magnetic fields. A static magnetic field, frequently in the presence of pulsing gradient magnetic fields, may be applied along one direction of the test subject using a primary coil, to align the nuclear spins of the test subject. This static magnetic field is often referred to as the Bₒ magnetic field. An RF coil may be oriented to produce a magnetic field having its B₁ magnetic field vector perpendicular to the direction of the Bₒ magnetic field, thus generating a resonance condition causing realignment of the nuclear spins in the test subject.

The desired operating frequency of the RF coil, and therefore the frequency of the RF excitation magnetic field, may depend on the magnitude of the Bₒ magnetic field. It may be desirable to operate the RF coil at the Larmor frequency of the test subject, which may depend on the magnitude of the Bₒ magnetic field, with a larger magnitude for the Bₒ magnetic field corresponding to a higher Larmor frequency. For example, a static Bₒ magnetic field of 1.5 Tesla (T) may correspond to a Larmor frequency of approximately 64 Megahertz (MHz), a 3 T Bₒ field may correspond to a Larmor frequency of approximately 127 MHz, a 7 T Bₒ field may correspond to a Larmor frequency of approximately 300 MHz, a 9 T Bₒ field may correspond to a Larmor frequency of approximately 400 MHz, and an 11.7 T Bₒ field may correspond to a Larmor frequency of approximately 500 MHz. Thus, it may be desirable to operate an RF coil at such frequencies, as an example.

However, it may be difficult to operate an RF coil at higher frequencies, for example at 127 MHz and above. At such operating frequencies, the free space wavelength of the magnetic field produced by the RF coil may decrease to the point of approaching the size (e.g., diameter) of the RF coil, which may result in the coil behaving as a radiating antenna rather than a coil. Moreover, it may be difficult to tune an RF coil at high frequencies (e.g., 127 MHz, 300 MHz, 400 MHz, 500 MHz, etc.), meaning it may be difficult to achieve a resonant state, in which the reactance of the coil is approximately zero.

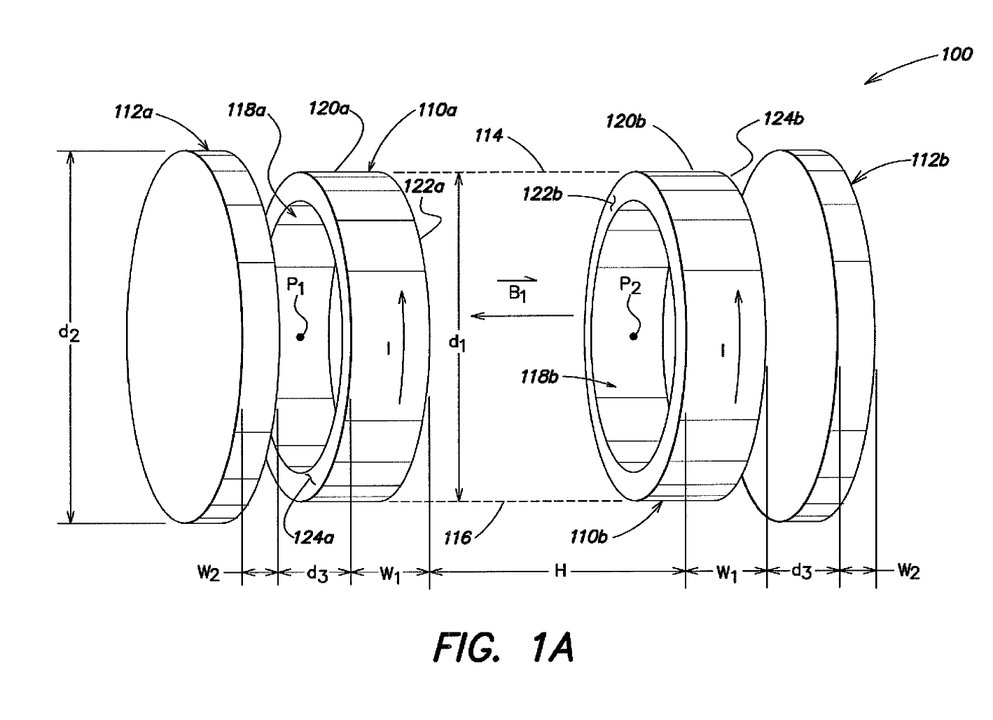

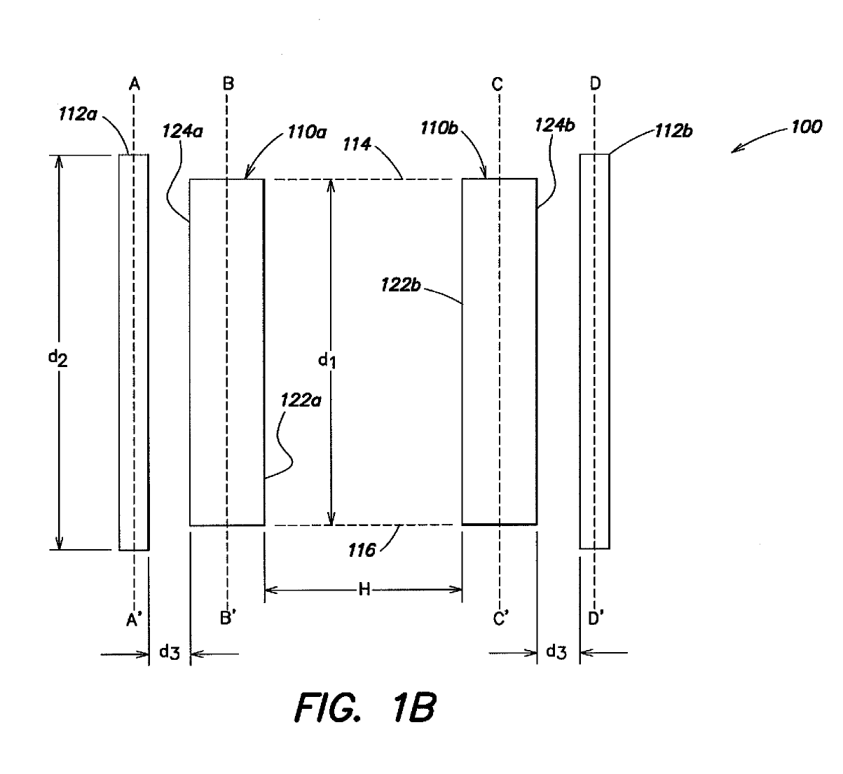

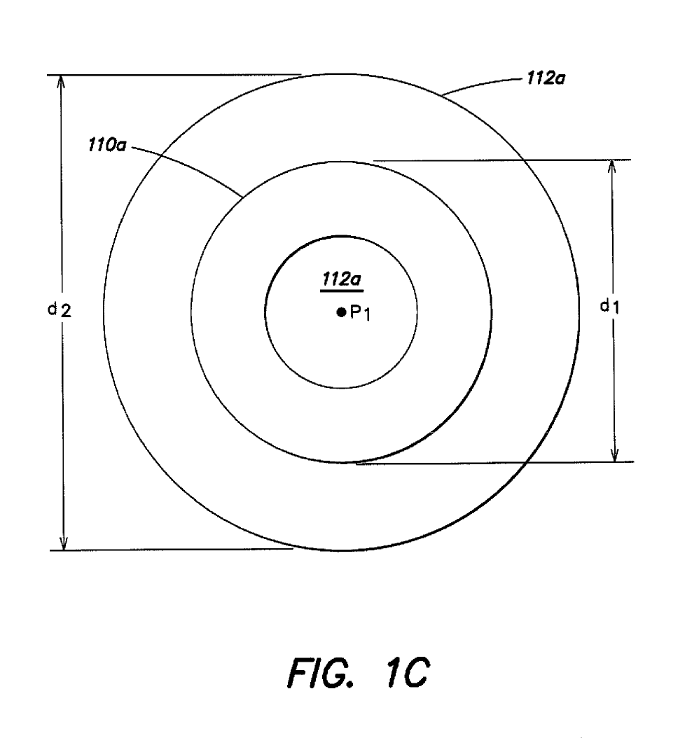

FIGS. 1A and 1B illustrate an RF coil configuration in which non-magnetic elements are provided with a Helmholtz pair of RF coils, and which may provide accurate operation at high frequencies. FIG. 1A illustrates a slightly angled view of the coil configuration 100. As shown, the coil configuration 100 comprises two RF coils, 100a and 110b, as well as two elements, 112a and 112b . According to some aspects, the elements 112a and 112b are non-magnetic. Such non-magnetic elements may have a relative magnetic permeability of one, or approximately one, according to some embodiments. In addition, the elements 112a and 112b may also be highly reflective of electromagnetic (EM) waves. For example, metals (either pure or in the form of alloys), such as copper, may exhibit both properties, being both non-magnetic and highly reflective of EM waves. However, other materials being both non-magnetic and highly reflective of EM waves may also be used, whether now-known or later developed. For ease of explanation, the elements 112a and 112b, as well as other similar elements described herein, are described as being non-magnetic metal elements.

As will be described in greater detail below, the non-magnetic metal elements may be designed and positioned, or positionable, to perform one or more functions, such as facilitating tuning of the RF coils, and modifying the magnetic field produced by the RF coils. It should be appreciated that the Helmholtz configuration of FIG. 1A may be used in different modes, such as for transmit mode only, receive mode only, or for both transmit and receive modes. In addition, the two RF coils may operate in different modes, for example if RF coil 110a operates in transmit mode, and if RF coil 112b, electromagnetically coupled to one or both of the non-magnetic elements 112a and 112b, operates in receive mode. Other modes of operation are also possible. The function(s) performed by the non-magnetic metal elements 112a and 112b may depend on the mode of operation of the RF coils.

In the non-limiting example of FIGS. 1A and 1B, RF coils 110a and 110b are identical to each other and non-magnetic metal elements 112a and 112b are identical to each other. It should be appreciated that this is just an example, and that the RF coils may not be identical in all embodiments, and that the non-magnetic metal elements may not be identical in all embodiments.

In the non-limiting example of FIGS. 1A and 1B, the RF coils 110a and 110b are arranged as a Helmholtz coil pair. They each have a diameter d₁, and are separated from each other by a distance H, equal to one-half of the diameter d₁ (i.e., H=d₁/2), or in other words equal to the radius of each coil. Their relative positioning defines a cylindrical volume therebetween, outlined by the dashed lines 114 and 116. Each of the RF coils may carry a substantially identical electrical current I flowing in the same direction in each of the coils, which may be an alternating current (AC). As a result of the current I flowing in each of the RF coils 110a and 110b, a magnetic field \vec{B}₁ may be generated therebetween.

The structural form and positioning of the RF coils in FIG. 1A is non-limiting. In the example of FIG. 1A, the RF coils 110a and 110b are ring-shaped, having cylindrical outer surfaces 120a and 120b, respectively. They also each contain an air gap 118a and 118b, respectively. However, it should be appreciated that such air gaps may not be present in all embodiments, as the various aspects of the invention are not limited in this respect. Furthermore, FIG. 1A illustrates that each of the RF coils 110a and 110b is symmetric about a respective central point, P1 and P2, in that P₁ may lie on a central axis of ring-shaped RF coil 110a, and P₂ may likewise lie on a central axis of ring-shaped RF coil 110b. It should be appreciated that the central points P1 and P2 may be conceptual and need not be embodied by any physical structure. Furthermore, it should be appreciated that the ring-shaped nature of RF coils 110a and 110b, as well as their symmetric nature, is non-limiting, as one or both of the RF coils 110a and 110b may take any suitable shaping and configuration. For example, one or both of the outer surfaces 120a and 120b may be substantially elliptical, substantially rectangular, have an irregularly shaped boundary, or take any other suitable form. Likewise, the RF coils may not be symmetrical about the central points, and, depending on the shape of the RF coils, there may not be an identifiable central point in all embodiments. Furthermore, each of the RF coils 110a and 110b may have any suitable width W₁, including negligible width (e.g., a conducting sheet or strips), for example if the RF coils are each formed of strip conductors provided in the planes defined by inward facing surfaces 122a and 122b.

The RF coils 110a and 110b may employ any suitable conductor type and configuration. For example, as mentioned, the RF coils 110a and 110b may each employ microstrip conductors disposed on a respective inward facing surface, or side, 122a and 122b. In such embodiments, the conductors may be mounted on a non-conducting backing, and the width W₁ may be small, for example 2 centimeters (cm), 1 cm, less than 1 cm, or any other suitable width. Alternatively, or in addition, the RF coils may include conductors in the form of conventional wiring wrapped around a cylindrical support (e.g., around outer surfaces 120a and 120b), conducting tubes, or any other suitable conductor configuration. According to some embodiments, the conductor may be segmented (e.g., segmented microstrips of uniform or varying lengths). If the conductor is segmented, any suitable number of segments may be used, for example between two and twenty segments, or any other number. In addition, if the conductor is segmented, one or more tuning capacitors may be placed between one or more of the segments. The tuning capacitors between segments of a segmented conductor may have identical values, or may have differing values. According to one embodiment, an RF coil employs a segmented conductor having segments of differing lengths with tuning capacitors of differing values between the various segments. Moreover, according to some aspects, the RF coils may be supplied by any suitable power supply (not shown), which may comprise a single power supply for each of the RF coils 110a and 110b, or a single power supply for the pair of coils, or any other suitable power supply configuration. No power supply may be provided if the RF coils operate only as receivers.

As mentioned, the coil configuration 100 further comprises non-magnetic elements 112a and 112b, the presence of which may provide various operating scenarios, and which are described as being metal for purposes of explanation. For example, the non-magnetic metal elements 112a and 112b may enable accurate tuning of the RF coils 110a and 110b at various operating frequencies, such as at 64 MHz, 126 MHz, 200 MHz, 300 MHz, and 400 MHz, as a few non-limiting examples. The non-magnetic metal elements may also modify the magnetic field(s) produced by the RF coils 110a and 110b, for example, deflecting, concentrating, strengthening, focusing, or otherwise modifying the magnetic field(s). As used herein, the term “focus” does not require focusing to a point, but rather may also include focusing to a region or volume. In some embodiments, the non-magnetic metal elements may act as magnetic lenses, and may enable control over a magnetic field between the RF coils 110a and 110b, such as controlling the size and shape of an area of uniform magnetic field strength. The various characteristics of the non-magnetic metal elements 112a and 112b shown in FIGS. 1A-1C, such as their dimensions and positioning, may be chosen to provide desired operating characteristics, such as tuning and magnetic field modification.

FIGS. 1A-1C show one non-limiting example of a configuration of non-magnetic metal elements that may facilitate tuning the RF coils 110a and 110b, while also providing magnetic field modification capabilities, for example by being electromagnetically coupled to the RF coils 110a and 110b. Each of the non-magnetic metal elements 112a and 112b is illustrated as a cylindrical element (e.g., a disc) having a diameter d₂, and thickness W₂. The diameter d₂ and the width W₂ may take any values, as the various aspects of the invention are not limited in this respect. For example, the diameter d₂ is illustrated as being greater than the diameter d₁. However, in some embodiments, d₂ may be equal to, or less than d₁, and the amount of difference between d₁ and d₂ may take any suitable value. Similarly, the width W₁ may take any suitable value relative to the width W₂, for example being smaller than W₂, equal to W₂, or greater than W₂. Furthermore, it should be appreciated that one or both of the non-magnetic metal elements 112a and 112b may not be cylindrical, and need not be the same shape as the RF coils (e.g., ring-shaped in the example of FIG. 1A). For example, the non-magnetic metal elements of some embodiments may be square, rectangular, elliptical, irregularly shaped, or take any suitable shape. Moreover, the non-magnetic metal elements need not be formed of a solid piece of material in all embodiments, but rather may include one or more holes, openings, or apertures, and may be formed of two or more connected pieces or segments, as described further below.

In FIGS. 1A-1B, the positioning of the non-magnetic metal elements 112a and 112b is identical with respect to the respective RF coils 110a and 110b, although this need not be the case in all embodiments. As shown, the non-magnetic metal element 112a is provided proximate a first side 124a of the RF coil 110a, such that it is outside of the central volume defined between the RF coils 110a and 110b and outlined by the dashed lines 114 and 116. The non-magnetic metal element 112a is separated from the RF coil 110a by a distance d₃, which may take any suitable value, such as two centimeters, six centimeters, or any other suitable value, and which may be adjustable, or variable, in some embodiments. Also, the distance of separation between the non-magnetic metal element and the RF coil may not be uniform. According to some embodiments, such as that shown in FIGS. 1A-1B, the non-magnetic metal element may be electrically isolated from the RF coil such that electric current does not flow between the two. Moreover, in some embodiments the non-magnetic metal element 112a may be positioned at least partially inside the air gap 118a, assuming the diameter d₂ is smaller than the diameter d₁. The non-magnetic metal element and the RF coil may be physically connected, for example by posts or spacers, or may each have a support frame, or may be secured in any other suitable manner, for example by mounting to a table, a floor, or a wall surface of an MRI machine bore.

Similarly, the non-magnetic metal element 112b is disposed on a first side 124b of the RF coil 110b, such that it is outside of the central volume defined between the RF coils 110a and 110b and outlined by the dashed lines 114 and 116. The non-magnetic metal element 112b is also separated from the RF coil 110b by the distance d₃, which again may take any suitable value, and which may be adjustable, or variable, in some embodiments. In FIGS. 1A and 1B the non-magnetic metal elements 112a and 112b are not physically connected to the RF coils, although they may be electromagnetically coupable to the RF coils. However, it should be appreciated that in some embodiments the non-magnetic metal elements may be physically connected, or secured, to the RF coils, for example by non-conducting posts, spacers, screws, clips, or any other suitable structure(s). In addition, or alternatively, each of the RF coils may have its own support structure (e.g., a non-conducting frame or backing) to facilitate positioning of the coil.

FIG. 1B further illustrates the positioning of the coil configuration 100. In particular, FIG. 1B illustrates a side view of the coil configuration 100 of FIG. 1A. As illustrated in the non-limiting example of FIG. 1B, the various components of the coil configuration 100 may be positioned in substantially parallel planes. For example, as shown, the non-magnetic metal element 112a may be substantially planar and may lie within the plane defined by the dashed line A-A′. The RF coil 110a may lie substantially within a plane defined by the dashed line B-B′, which plane may be substantially parallel to plane A-A′. Similarly, the RF coil 110b may be substantially planar, and lie within the plane defined by the dashed line C-C′. The non-magnetic metal element 112b may be substantially planar, and may lie within the plane defined by dashed line D-D′. All four of the illustrated planes (A-A′, B-B′, C-C′, and D-D′) may be substantially parallel. However, it should be appreciated that in various embodiments the illustrated parallel nature of the planes need not be present. For example, one or more of the RF coils and/or non-magnetic metal elements may not be planar, but rather may be curved, or may take any other shape. Furthermore, the RF coils and non-magnetic metal elements may not be parallel to each other in all embodiments, as the various aspects of the invention are not limited in this respect. According to some aspects, a non-magnetic metal element may be angled relative to an RF coil to direct, focus, or otherwise shape the magnetic field of the RF coil in a desired manner.

FIG. 1C further illustrates an end-on view of the RF coil 110a and non-magnetic metal element 112a (i.e., looking from the central point P₂ toward the central point P₁ in FIG. 1A). As illustrated, the RF coil 110a and non-magnetic metal element 112a are arranged concentrically. Because of airgap 118a of RF coil 110a, illustrated in FIG. 1A, the non-magnetic metal element 112a can be seen through the center of the RF coil 110a in the view of FIG. 1C. As mentioned previously, the airgap 118a is optional, and may not be present in all embodiments. For example, the RF coil may be formed of a conducting loop mounted on a solid non-conducting backing (i.e., a backing having no hole at its center), in which case the non-magnetic element 112a would not be visible at the center of FIG. 1C because there would not be an air gap in the non-conducting backing. FIG. 1C illustrates the symmetrical nature of the RF coil 110a and the non-magnetic element 112a with respect to central point P₁, as previously mentioned. As shown, RF coil 110a and non-magnetic element metal 112a are each ring-shaped, with their respective centers corresponding to central point P₁. The symmetrical configuration illustrated in FIG. 1C is non-limiting, as other configurations are possible.

As mentioned, the non-magnetic metal elements 112a and 112b may enable or facilitate tuning of the RF coils 110a and 110b. For example, the non-magnetic metal elements may be provided to be electromagnetically coupled to the RF coils, allowing formation of a resonant system. The RF coils may each have an impedance, which may be a combination of inherent (e.g., distributed impedances of the coil conductor) and lumped, or external, resistances, capacitances, and inductances, and which may therefore include both a resistance and a reactance. This impedance may be referred to as a “primary” impedance for purposes of explanation. During operation, the RF coil 110a may be electromagnetically coupled to the non-magnetic metal element 112a and/or 112b, to create a resonant system comprising the RF coil 110a and the non-magnetic metal element(s) to which it is electromagnetically coupled. It should be appreciated that a resonant system is one which exhibits resonant behavior, and may be characterized by a reactance that is equal to zero, or approximately equal to zero. However, the resonant system may have a non-zero resistance.

The electromagnetic coupling of the RF coil and the non-magnetic metal element(s) may create a resonant system (at one or more frequencies) by generating a secondary impedance resulting from the provision of the non-magnetic metal element(s), in the form of a resistance, capacitance, inductance, or some combination of the three. The secondary impedance may combine with the primary impedance of the RF coil, resulting in a total impedance of the system comprising the RF coil and the non-magnetic metal element(s) to which the RF coil is coupled, which may also be referred to as an effective impedance of the RF coil. The effective impedance may be lower than the primary impedance at some frequencies. For example, as mentioned, the RF coil may have a non-zero impedance, including a non-zero resistance and/or a non-zero reactance, at a particular input frequency or range of frequencies. The electromagnetic system comprising the RF coil and the non-magnetic metal element(s) to which the RF coil becomes electromagnetically coupled may form a resonant system, therefore having a reactance equal to zero, or approximately equal to zero, at the given input frequency or frequencies. It should be appreciated that electromagnetic systems may have several resonant frequencies, and that the system may be designed to display a particular resonant frequency or frequencies while also having additional resonant frequencies.

Similarly, during operation, the RF coil 110b may be electromagnetically coupled to the non-magnetic metal element 112b and/or 112a, decreasing its effective impedance for a given frequency or range of frequencies by creating a resonant system comprising the RF coil 110b and the non-magnetic metal element(s). Thus, the coil configuration 100 may be tuned to produce a resonant system at any frequency within approximately ±5% of 64 MHz, 126 MHz, 300 MHz, 400 MHz, 500 MHz, or any other frequencies. Proper tuning may allow for the RF coils 110a and 110b to generate large magnetic fields, and may facilitate imaging of a test subject during MRI, for example.

It should also be appreciated that while it has been described that a resonant system may be created comprising a single RF coil and one or more non-magnetic elements, which may be metal or any other material that may be both non-magnetic and highly reflective of EM waves (e.g., EM waves generated by the RF coil), the resonant system may be created by the provision of other components. For example, a single resonant system may be created comprising two RF coils and two non-magnetic metal elements (e.g., coil configuration 100), by suitable electromagnetic coupling of the RF coils and the non-magnetic metal elements. Furthermore, any number of RF coils and non-magnetic metal elements may be provided to generate a resonant system by suitable electromagnetic coupling, for exampling by proper positioning of the components.

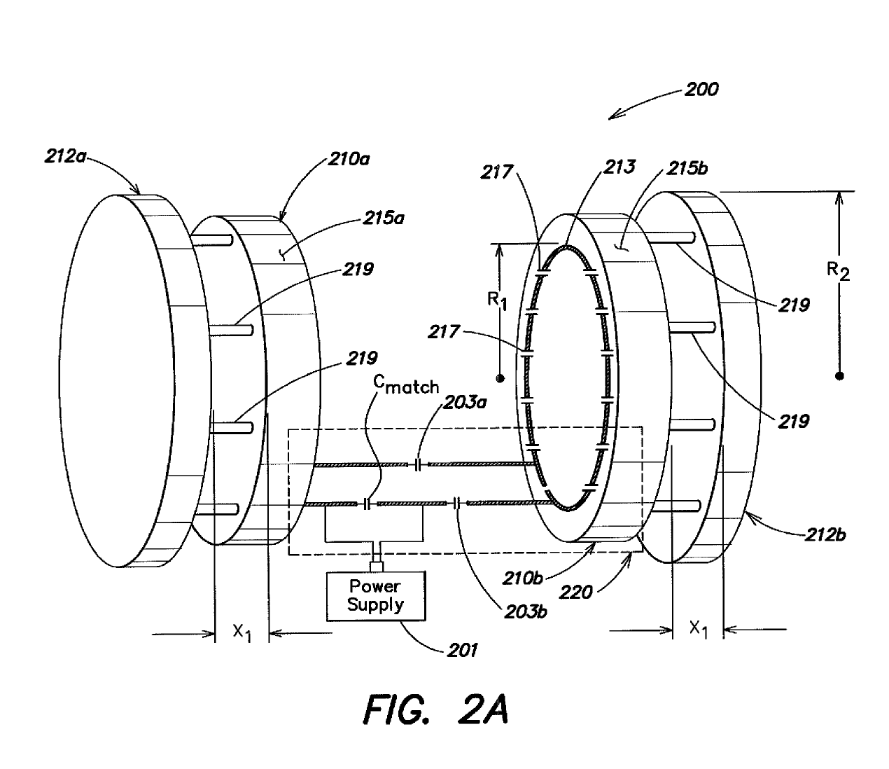

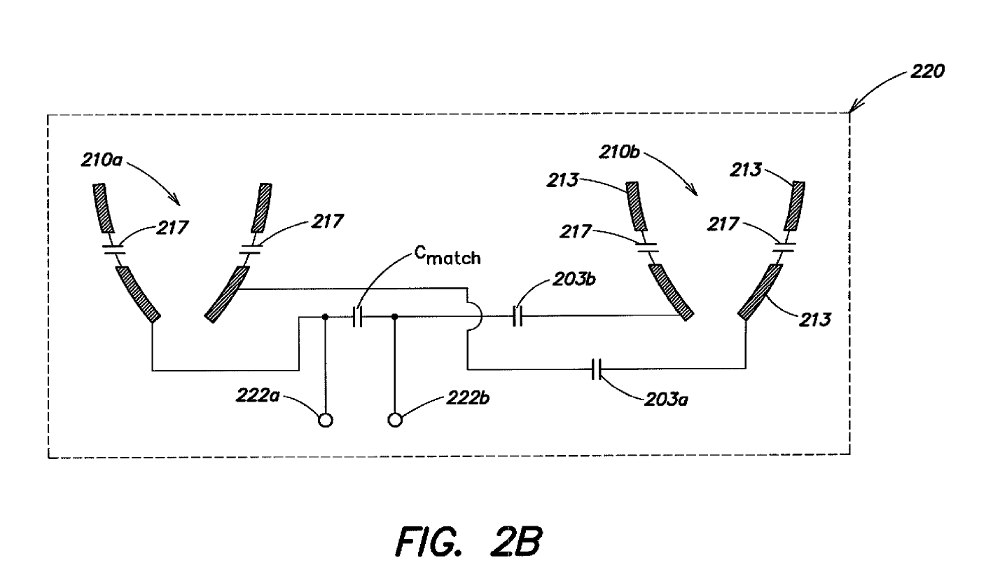

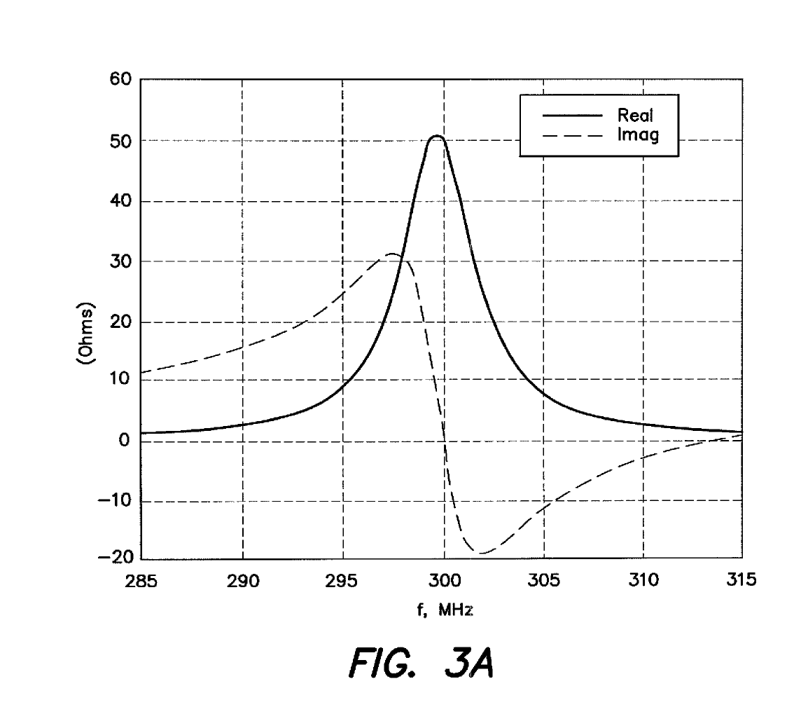

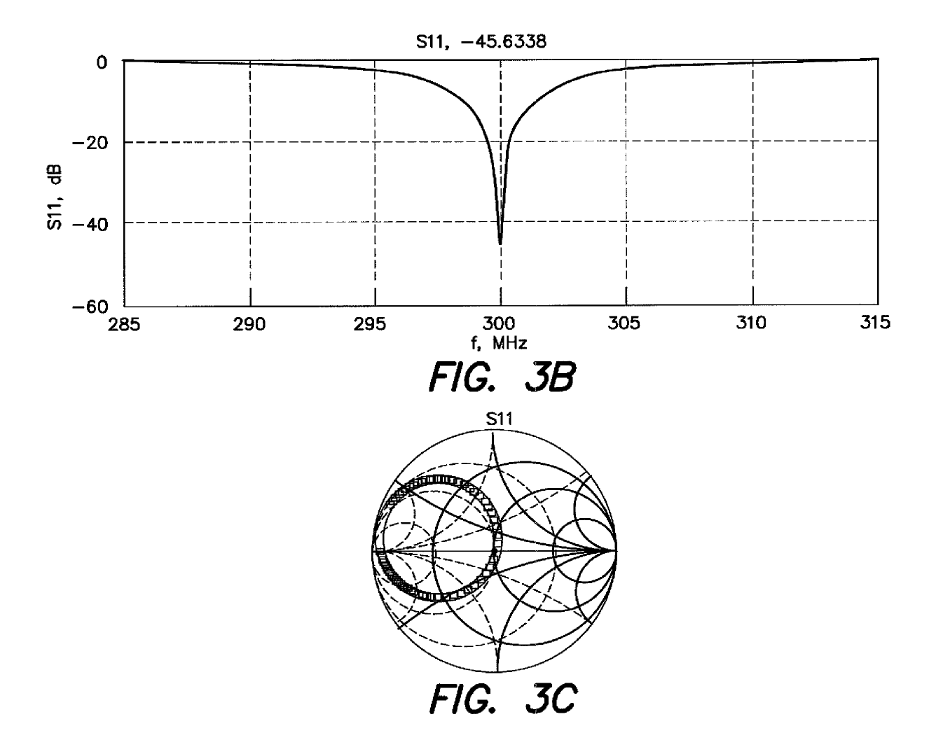

FIGS. 2A-2B and 3A-3C provide a non-limiting example of the tuning functionality of non-magnetic metal elements in combination with an RF coil, according to an aspect of the invention. FIG. 2A illustrates a specific embodiment of the coil configuration 100 of FIG. 1A, and FIGS. 3A-3C illustrate the frequency response of the RF coil configuration 200 of FIG. 2A.

As shown in FIG. 2A, the RF coil configuration 200 comprises two RF coils, 210a and 210b. Each of the RF coils comprises a strip conductor having twelve conducting segments, mounted on a non-conducting backing, or support. Specifically, RF coil 210b is formed of a segmented conductor 213 having twelve segments mounted on non-conducting support 215b, formed of plexiglass or any other suitable non-conducting material. In the non-limiting example of FIG. 2A, each of the twelve segments of conductor 213 has an approximately equal length, and the segments are interconnected, or bridged, by capacitors 217, which may be tuning capacitors facilitating tuning of the RF coils. However, it should be appreciated that according to some embodiments segmented conductors of an RF coil may have segments of unequal lengths. In the non-limiting example of FIG. 2A, each of the capacitors 217 has a value of 5.8 picoFarads (pF). However, other capacitive values may be used in different embodiments. Also, according to some embodiments, capacitors interconnecting segments of a segmented conductor of an RF coil may have unequal values, as the various aspects are not limited in this respect.

The radius from the central point of the RF coil 210b to the outer edge of the segmented conductor 213 is equal to R₁. In the non-limiting example of FIG. 2A, the RF coil 210a is identical to the RF coil 210b, so that the RF coil 210a also comprises a segmented strip conductor mounted on a non-conducting support 215a. The thicknesses of the non-conducting supports 215a and 215b can take any values, including having negligible width. Also, the conductor of RF coil 210a is not visible given the angle of the view shown in FIG. 2A.

The RF coils 210a and 210b are each configured to receive an RF input signal from power supply 201, which may be any suitable type of power supply, such as an RF power supply provided by an MRI instrument, or any other suitable power supply. Also, it should be appreciated that no power supply may be provided in embodiments in which the RF coils 210a and 210b operate only as receivers. In such embodiments, the RF coils 210a and 210b may be connected to a co-axial cable, for example, to read signals out of the RF coils, rather than to a power supply.

The interconnection between the RF coils is illustrated in FIG. 2A, and is shown in greater detail in FIG. 2B, which focuses on the area encompassed by the dashed box 220. It should be appreciated that FIG. 2B does not show the same relative angles of the components as shown in FIG. 2A, but rather provides a modified view so that portions of the conductors of both RF coils 210a and 210b are visible. As shown, one segment of the conductor 213 of RF coil 210b is connected to a segment of the conductor of RF coil 210a by a capacitor 203a. Similarly, one segment of the conductor of RF coil 210a is connected to a segment of the conductor 213 of RF coil 210b by a capacitor 203b. The values of capacitors 203a and 203b may be the same as the values of capacitors 217, or may be different in some embodiments. As shown, the interconnection including capacitor 203a may be crossed over the interconnection including capacitor 203b to insure proper current flow in the RF coils.

Furthermore, FIG. 2B shows that the interconnection of the conductors of the RF coils 210a and 210b may include a matching capacitor, C_{match}. The matching capacitor C_{match} may facilitate matching of the RF coils to a characteristic impedance of a feed line (e.g., 50 Ohms, 75 Ohms, or any other value) connected to terminals 222a and 222b, which may be, for example, positive and negative terminals, signal and ground terminals, or any other suitable terminals. For example, in the non-limiting example of FIG. 2A, the terminals 222a and 222b (not shown in FIG. 2A) may be connected to a power supply, and the matching capacitor may have a value suitable for matching the RF coils to the power supply line. According to some embodiments, the RF coils 210a and 210b may be configured as receivers, and may therefore provide output signals, for example by suitable connection of the terminals 222a and 222b to an output line, such as a coaxial cable. As one non-limiting example, the matching capacitor C_{match} has a value of 26 pF. However, it should appreciated that other values of the matching capacitor may be chosen to provide suitable matching for a given feed line.

Referring again to FIG. 2A, the coil configuration 200 further comprises two non-magnetic metal elements, 212a and 212b. The non-magnetic metal element 212a is secured to the RF coil 210a by non-conducting posts, or spacers, 219. Likewise, the non-magnetic metal element 212b is secured to the RF coil 210b by non-conducting posts 219. The distance of separation, X₁, between RF coil 210a and non-magnetic metal element 212a is equal to 3.1 centimeters in this non-limiting example, which is the same as the distance between RF coil 210b and non-magnetic metal element 212b. It should be appreciated that other values for X₁ are also possible, as the various aspects of the invention are not limited to any particular spacing between an RF coil and a non-magnetic metal element. The radius of each of the non-magnetic metal elements 212a and 212b is equal to R₂, which in this non-limiting example is equal to approximately 6 inches (i.e., approximately 15 cm), and which is also approximately equal to R₁ plus 3 centimeters. In the non-limiting example of FIG. 2A, the non-magnetic metal elements 212a and 212b, as well as the conductors of the RF coils (i.e., conductor 213), are formed of copper.

As mentioned previously, RF coils, such as RF coils 210a and 210b, may each have an impedance associated therewith. The impedance of each RF coil may be the result of inherent resistances, capacitances, and inductances of the coil, for example due to the coil material (e.g., distributed impedances), as well externally connected, or lumped, impedances, such as the capacitors 217. When the RF coils are excited by the power supply 201 with a RF input signal, they may become electromagnetically coupled to one or both of the non-magnetic metal elements 212a and 212b. The electromagnetic coupling may generate a resonant system at a particular frequency, or range of frequencies, comprising both RF coils 210a and 210b and the non-magnetic metal elements 212a and 212b.

FIGS. 3A-3C illustrate that tuning of the RF coil configuration 200 of FIG. 2A may be achieved at a frequency of approximately 300 MHz. For example, as shown in FIG. 3A, the impedance of coil configuration 200, which may include both real and imaginary components, varies as a function of frequency. The solid line illustrates the frequency-dependent behavior of the resistance (i.e., the real part of the impedance) of the system, while the dashed line represents the frequency-dependent behavior of the reactance (i.e., the imaginary part of the impedance). The y-axis is in units of Ohms. The frequency is plotted on the x-axis in units of MHz. As shown, the coil configuration of FIG. 2A was tuned to a frequency of approximately 300 MHz (the Larmor frequency corresponding to a 7 T Bₒ magnetic field in an MRI machine), such that the imaginary component (i.e., the reactance) of the impedance at 300 MHz is approximately zero (i.e., a resonant state is achieved), and the real component was matched to approximately 50 Ohms. The coil configuration may be designed to meet any desired matching parameters (e.g., 50 Ohms, 75 Ohms, or any other suitable value). Also, it should be appreciated that matching the resistance to a particular value (e.g., 50 Ohms) does not require in every embodiment that the RF coil itself have an actual resistance of the matched value (e.g., 50 Ohms). It should be appreciated that the coil configuration 200 may be tuned to other frequencies by suitable design, and that 300 MHz is just one non-limiting example. In addition, it should be appreciated that the system may be tuned around the center frequency of 300 MHz in the non-limiting example of FIG. 3A, meaning for example that the system may be tuned to any frequency within plus or minus (±) 5% of the center frequency (e.g., 300 MHz), plus or minus 3% of the center frequency, plus or minus 1% of the center frequency, or within any suitable range.

FIG. 3B illustrates the magnitude of the input reflection coefficient, also known as the scattering parameter S11, of the coil configuration 200 of FIG. 2A, and, like FIG. 3A, shows that resonant behavior can be achieved for the coil configuration. In particular, FIG. 3B shows that the scattering parameter S11 approaches approximately negative 46 dB (i.e., −46 dB), and more specifically −45.6 dB, at 300 MHz, indicating the coil configuration is matched to approximately 50 Ohms at that frequency. FIG. 3C is a Smith Chart displaying the magnitude and phase of the scattering parameter S11 in the complex reflection coefficient plane. The center point of FIG. 3C represents 50 Ohms.

It should be appreciated that FIG. 2A merely illustrates one non-limiting implementation of an aspect of the present invention. Other configurations are possible. Similarly, different values for the various components illustrated in FIGS. 2A and 2B may be used. For example, the capacitor values given are merely exemplary, as are the dimensions and distances given for FIGS. 2A and 2B.

Thus, it should be appreciated that according to one aspect of the invention, a method of tuning a radio frequency coil comprises providing a non-magnetic metal element to facilitate tuning. The RF coil, for example RF coil 110a in FIG. 1A, may be excited with an RF input signal, such as an input voltage provided by a suitable power supply. As mentioned, the RF coil 110a may have an impedance associated therewith, for example in the form of an inherent resistance, capacitance, and/or inductance, and/or external impedances provided by lumped resistors, capacitors, and/or inductors. By exciting the RF coil with an RF input signal, the RF coil may produce an electric and/or magnetic field electromagnetically coupling the non-magnetic metal element 112a to the RF coil 110a. Such electromagnetic coupling may generate a resonant system having approximately zero reactance, thus enabling resonant behavior.

Various parameters of the RF coil configuration (e.g., RF coil configuration 100) may impact the tuning behavior of the non-magnetic metal element. For example, the material of the non-magnetic element may be a factor in the amount of tuning provided. The material may be a metal, either pure or an alloy, or any other suitable material. Similarly, the shape, size, and positioning of the non-magnetic metal element 112a relative to the RF coil 110a may impact the tuning functionality provided by the non-magnetic metal element. Accordingly, these variables may be suitably selected to provide a desired amount of tuning, and the various aspects described herein are not limited to any particular materials, positioning, shaping, and/or sizing of the non-magnetic metal elements. For example, the spacing between a non-magnetic metal element and an RF coil may be adjusted to alter the electromagnetic coupling between the two, either between uses or during excitation of the RF coil.

As previously mentioned, non-magnetic metal elements may also be used to modify the magnetic fields produced by one or more RF coils. For example, the non-magnetic metal elements 112a and 112b in FIG. 1A may modify the magnetic field produced by the Helmholtz pair of RF coils 110a and 110b. The non-magnetic metal elements may modify the magnetic field in various manners, for example by deflecting the magnetic field, concentrating the magnetic field, containing or shielding the magnetic field, strengthening the magnetic field, and/or focusing the magnetic field, as some examples. The type and degree of modification may depend on the element material, positioning, and sizing, as will be described further below.

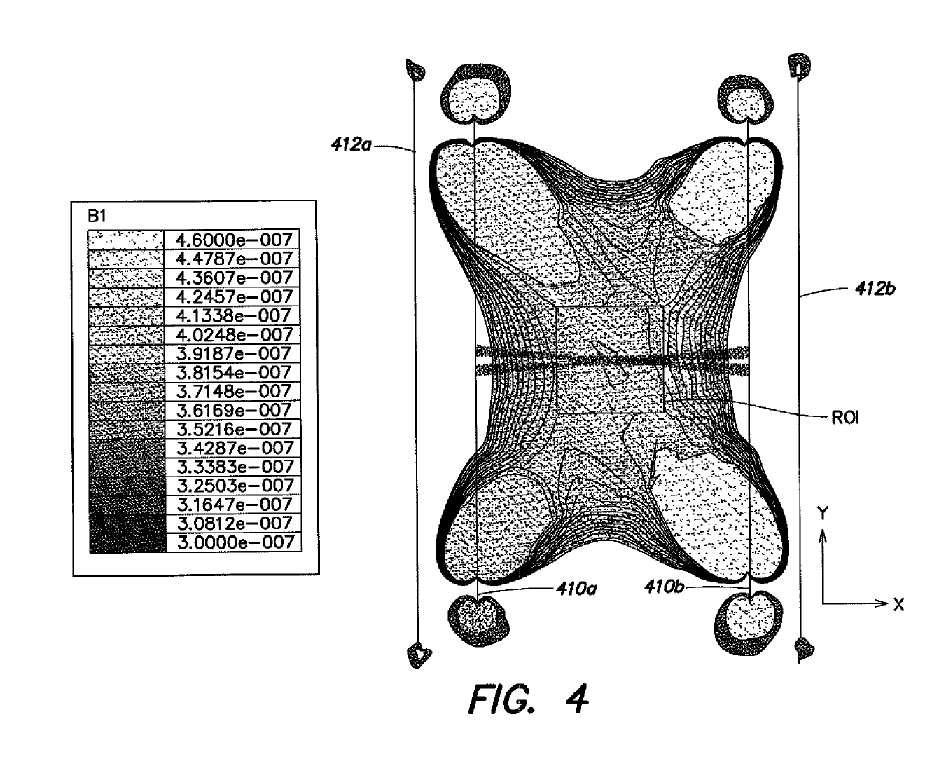

FIG. 4 illustrates a magnetic field map generated by finite element analysis for an RF coil configuration having two RF coils arranged as a Helmholtz pair, in combination with two non-magnetic metal elements. The simulation shows the magnitude and contours of the magnetic field (in units of Tesla) produced by the RF coils 410a and 410b tuned to 300 MHz, matched to 50 Ohms, and receiving an input power of 1 Watt (W), when non-magnetic metal elements 412a and 412b are positioned substantially parallel to the RF coils. The box in the center of the plot corresponds to a region of interest (ROI) measuring 6 cm by 6 cm, as might be desired in some MRI applications. As can be seen, the simulated configuration produces an area of approximately uniform magnetic field strength within the ROI. Moreover, the simulation results indicate that the variation of the magnetic field strength in the ROI is small. The variation in the magnetic field strength within the ROI can be quantified by finding the maximum and minimum magnitudes of the magnetic field in the ROI and comparing the maximum and minimum values to the magnetic field at the center of the ROI, as shown in Eq. (1):

$$Magnetic Field variation = max \{ \vert \frac{{B}_{1 max} - {B}_{1 center}}{{B}_{1 center}} \vert , \vert \frac{{B}_{1 min} - {B}_{1 center}}{{B}_{1 center}} \vert \} \qquad Eq . ( 1 )$$

where the maximum and minimum values are denoted B₁ₘₐₓ and B₁ₘᵢₙ, respectively, and the magnetic field value at the center of the ROI is B_{1center}. Further, in Eq. (1), the magnetic field B₁ may be recorded as a polarized field in the form B₁=(Bₓ−jB_{y})/2, where Bₓ and B_{y} refer to the x and y components of B₁, respectively. The simulation results of FIG. 4 indicate that the magnetic field variation is approximately 14.49% throughout the ROI, which is smaller than can be achieved with a conventional RF coil configuration. Moreover, the magnitude of the magnetic field beyond the non-magnetic metal elements in FIG. 4 (i.e., to the right and left of the non-magnetic metal elements in the figure) is small, indicating that the non-magnetic metal elements may contain the magnetic field between them.

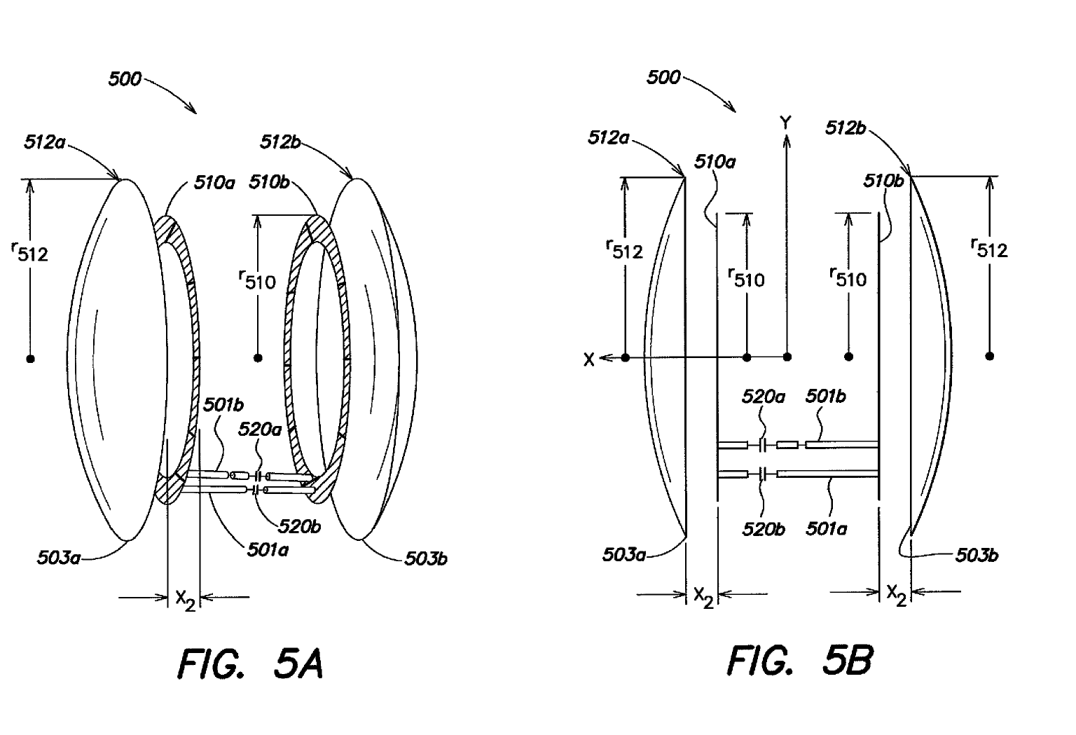

While the simulation results of FIG. 4 illustrate one type of modification of a magnetic field produced by an RF coil that may result from the use a non-magnetic metal element, other forms of modification are also possible. For example, according to some aspects of the invention, non-magnetic metal elements may be used as magnetic lenses, to concentrate or focus a magnetic field produced by an RF coil. The material, sizing and shaping, and positioning of the non-magnetic metal element relative to an RF coil may be chosen to enhance the magnetic lensing function. FIGS. 5A and 5B illustrate an example.

The coil configuration 500 of FIG. 5A includes two RF coils, 510a and 510b. The two RF coils may be any type of RF coils, such as those described previously herein, or any other type of RF coils. As shown, the RF coils 510a and 510b are connected by interconnections 501a and 501b, which may be, for example, wires interconnecting segments of the conductors of the RF coils 510a and 510b. For example, the interconnection of the RF coils 510a and 510b may take the form of the interconnection shown in FIG. 2B for RF coils 210a and 210b. Thus, capacitors 520a and 520b may be provided with the interconnections 501a and 501b, for example to operate as tuning capacitors similar to capacitors 203a and 203b in FIG. 2B. Similarly, according to some embodiments, a matching capacitor may be provided on one or more of the interconnections 501a and 501b, similar to matching capacitor C_{match} in FIG. 2B, to facilitate matching of the RF coils 510a and 510b to a feed line, such as from a power supply. It should be appreciated that the conductors 501a and 501b merely illustrate one non-limiting example of one type of electrical connection that can be provided between the RF coils 510a and 510b.

The coil configuration 500 also includes two non-magnetic metal elements, 512a and 512b. As opposed to the non-magnetic metal elements 112a and 112b of FIGS. 1A-1B, the non-magnetic metal elements 512a and 512b are concave, or curved, with each of the non-magnetic metal elements being concave toward the RF coils 510a and 510b. The amount, and type of curvature of the non-magnetic metal element(s) may be chosen to provide a desired amount and type of alteration of the magnetic field produced by an RF coil, and the various aspects described herein are not limited to any particular amount or type of curvature. For example, the non-magnetic metal element 512a may have a surface proximate the RF coil 510a, which surface may be defined by a smooth, spherical, or parabolic, curve. Alternatively, the non-magnetic metal element may have a segmented surface formed of a series of flat metal pieces, such that it does not form a smooth curve. These, as well as other types of curvature, are possible.

The sizing and positioning of the non-magnetic metal elements 512a and 512b may also be chosen to provide desired lensing functionality. For example, the non-magnetic metal element 512a may have a radius r₅₁₂ that is greater than, equal to, or less than a radius r₅₁₀ of the RF coils 510a and 510b. Similarly, each of the RF coils may be separated from a respective one of the non-magnetic metal elements by any suitable distance x₂, which may be non-uniform and/or adjustable in some embodiments.

The relative positioning of the components of the coil configuration 500 can be further appreciated by reference to FIG. 5B, which illustrates a side view of the RF coil configuration 500. As shown in FIG. 5B, each of the RF coils 510a and 510b may be substantially planar, and may be oriented in planes which are substantially parallel to each other. The non-magnetic metal element 512a, which again is concave, has a perimeter defined by 503a, which in the non-limiting example of FIGS. 5A and 5B is circular, however the perimeter may take any suitable shape, such as being elliptical, rectangular, irregularly shaped, or any other suitable shape. Similarly, the non-magnetic metal element 512b has a circular perimeter 503b. The perimeter 503a may be substantially planar, although it need not be in all embodiments, and lies in a plane which, as illustrated in FIG. 5B, may be substantially parallel to the plane in which RF coil 510a is disposed. Similarly, the perimeter 503b of non-magnetic metal element 512b may lie within a plane which may be substantially parallel to the plane in which RF coil 510b is disposed. Thus, in the non-limiting example of FIG. 5B, RF coils 510a and 510b and perimeters 503a and 503b are all substantially parallel. It should be appreciated that the various aspects of the invention are not limited in this manner, as, for example, one or both of the perimeters may not be planar and/or may be angled (rather than parallel) with respect to the RF coils.

Referring to FIG. 5B, it can be seen that the non-magnetic metal element 512a has a first side proximate the RF coil 510a and a second side distal the RF coil 510a. The non-magnetic metal element 512a is concave toward the RF coil 510a, such that it has a surface that is deflected from the perimeter 503a in a direction away from the RF coil 510a. Similarly, the non-magnetic element 512b is concave toward the RF coil 510b, such that it has a surface which is deflected from the perimeter 503b in a direction away from the RF coil 510b. According to some embodiments, the amount of deflection may be variable.

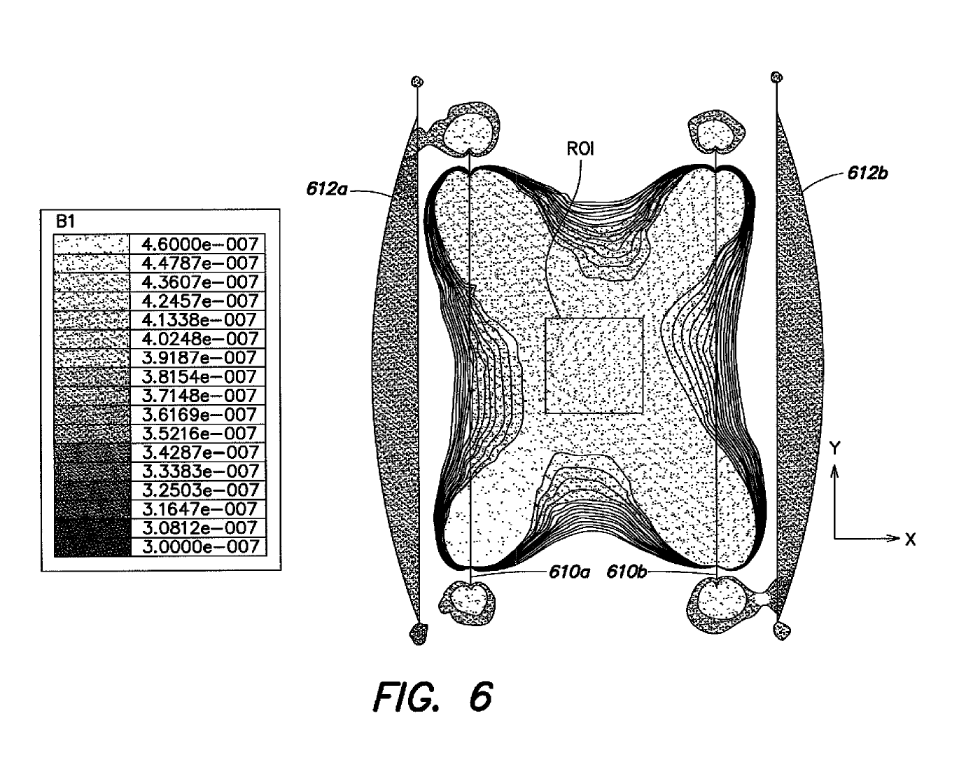

As mentioned, the non-magnetic metal elements 512a and 512b may operate as magnetic lenses, shaping the magnetic field(s) produced by the RF coils 510a and 510b. For example, the non-magnetic metal element(s) may be used as lenses to concentrate the magnetic field(s) produced by RF coils 510a and 510b. As an example, the RF coils 510a and 510b may be arranged as a Helmholtz pair, such that the separation between the two equals their radii. A Helmholtz coil pair is known to provide a region of approximately uniform magnetic field strength between the two coils. The non-magnetic metal elements 512a and 512b may increase, or otherwise alter, the area of uniform magnetic field strength, and may also reduce the magnetic field variation within the area of approximately uniform magnetic field strength. FIG. 6 illustrates an example.

FIG. 6 illustrates a magnetic field map generated by finite element analysis for a coil configuration similar to that in FIGS. 5A-5B, including parallel RF coils 610a and 610b arranged as a Helmholtz pair operating at 300 MHz, matched to a characteristic impedance of 50 Ohms, and receiving an input power of 1 W, with concave non-magnetic metal elements 612a and 612b positioned to act as magnetic lenses. The magnetic field map shows both the magnetic field strength, in Tesla, and contours for the configuration. Comparison to FIG. 4, which again was generated under similar operating conditions but with planar (flat) non-magnetic metal elements, shows that the concave non-magnetic metal elements of FIG. 6 increase the area of uniform magnetic field strength, such that it extends beyond the ROI. In addition, the magnetic field variation within the ROI, as calculated using Eq. (1), is approximately 8.05% for FIG. 6, which is significantly lower than the 14.49% variation for the configuration of FIG. 4. Thus, the use of concave non-magnetic metal elements in some embodiments may provide a larger area of substantially uniform magnetic field strength.

Furthermore, the non-magnetic metal elements may enable shaping of the area of approximately uniform magnetic field strength. For example, as mentioned, the non-magnetic metal elements 512a and 512b of FIGS. 5A-5B may be substantially circular, having circular perimeters 503a and 503b and a concave surface that is substantially spherical. Accordingly, the area of uniform magnetic field strength between the RF coils 510a and 510b may be substantially spherical. However, the non-magnetic metal elements of FIGS. 5A and 5B can take other shapes, for example having elliptical, rectangular, or irregularly shaped perimeters, among other possibilities. If the non-magnetic metal elements have elliptical perimeters, the area of uniform magnetic field strength between the RF coils 510a and 510b may be elliptical, or oblong, as opposed to spherical. Thus, the geometry of the area of uniform magnetic field strength may be defined by suitable selection of the shapes of the non-magnetic metal elements 512a and 512b.

As mentioned, the various aspects of the invention are not limited to any particular configuration of an RF coil with a non-magnetic metal element when operated as a magnetic lens. For example, the amount of deflection, or the amount of curvature, of a concave non-magnetic metal element may be chosen to provide a desired amount and type of alteration of the magnetic field produced by the RF coil. Similarly, the material from which the non-magnetic metal element is formed may be chosen to provide a desired amount of magnetic lensing. Moreover, the amount of curvature or deflection of the non-magnetic metal element may be variable, such that it may be changed during operation of the RF coil configuration, or between uses.

Furthermore, it should be appreciated that the magnetic lensing functionality is not limited to use with RF coils being operated as transmit coils. As described previously, RF coils may also be operated as receiver coils, for example in the context of MRI to detect response signals from a test subject which has been subjected to an excitation magnetic field. The receiver coil(s) may be the same coil(s) as the transmit coil, or a distinct coil. The use of a non-magnetic metal element in combination with an RF receiver coil, for example taking the configuration of FIG. 5A if the RF coils are operated as receiver coils, may enable defining the area from which the RF coil can detect a response signal, and/or increasing the sensitivity of detection of the RF coil to electromagnetic fields generated in, or arising from, the area. For example, the ROI illustrated in FIG. 6 may correspond to the area of a test subject from which it is desired to detect a response signal. The non-magnetic metal elements in FIG. 5A may improve the ability the RF coils 510a and 510b to detect electromagnetic fields from a similar ROI, while decreasing the likelihood that the RF coils will detect an electromagnetic field outside the ROI. Thus, according to some embodiments, non-magnetic metal elements may be provided with an RF receiver coil to improve the signal-to-noise ratio (SNR) of the receiver coil, for example by more than 10%, between 10-20%, by up to approximately 50%, or greater compared to systems lacking non-magnetic lensing elements. Thus, the SNR may be improved over conventional RF coils without the need to cryogenically cool the coil. The non-magnetic metal element material, sizing and shaping, and positioning relative to the RF receiver coil(s) may all be chosen to provide desired receiver functionality.

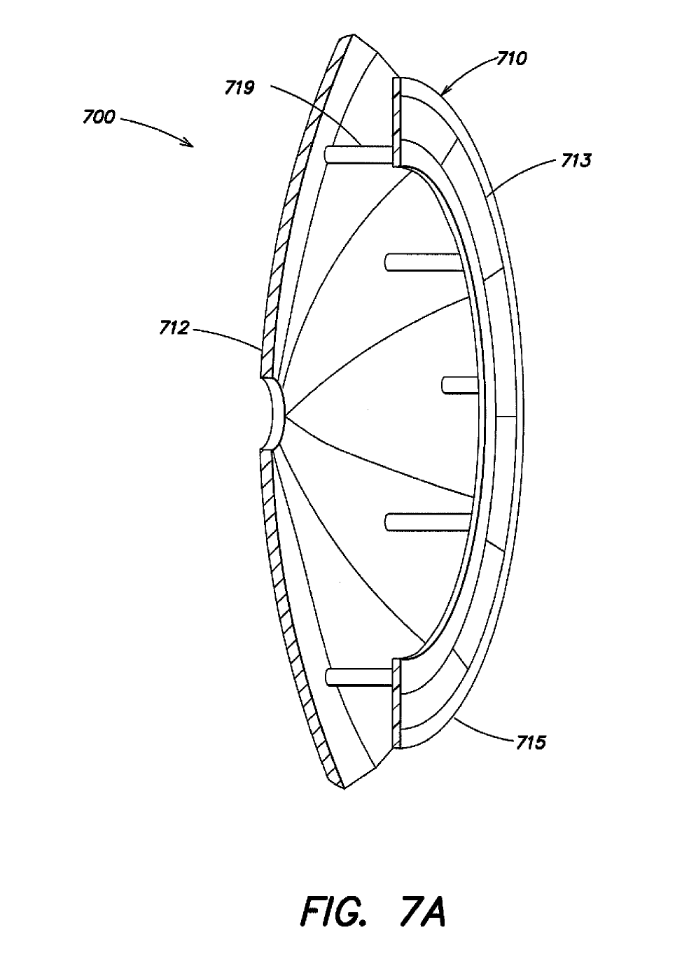

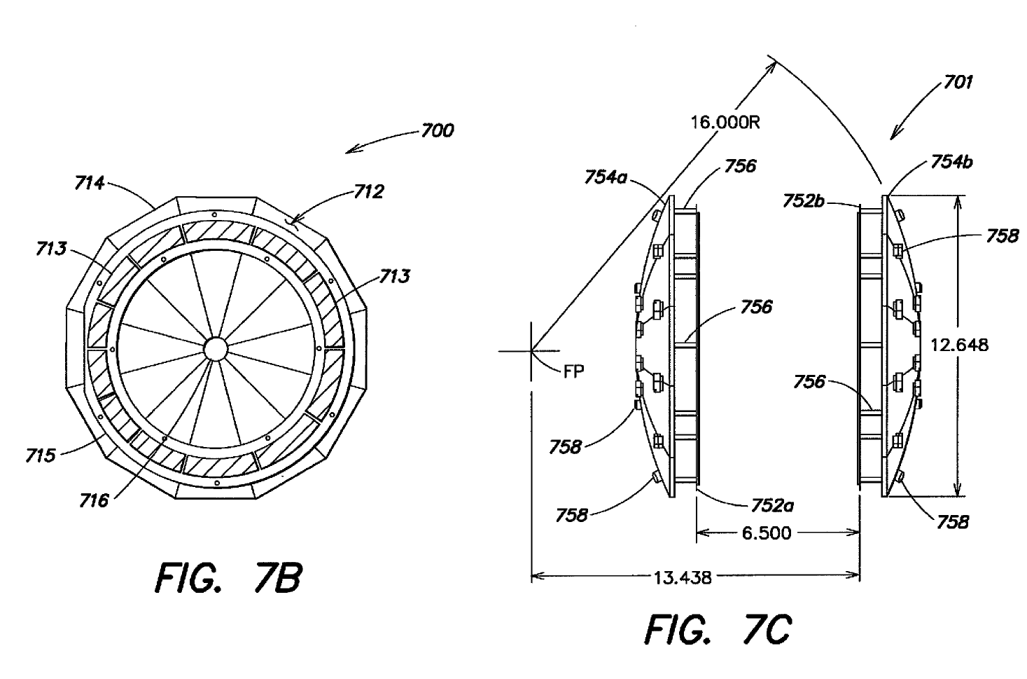

FIGS. 7A-7C illustrate one non-limiting exemplary implementation of an RF coil with a concave non-magnetic metal element. It should be appreciated that other configurations are possible. As shown in the side view of FIG. 7A, the structure 700 includes an RF coil 710 and a segmented non-magnetic metal element 712. Forming the non-magnetic metal element from segments, rather than a single piece of metal, may reduce eddy currents arising in the non-magnetic metal element.

The RF coil 710 is formed of a segmented conductor 713, which may have any suitable number and sizing of segments, and which may be formed of any suitable conducting material. The segmented conductor 713 is affixed to a non-conducting support 715, which may be formed of plexiglass, plastic, or any other suitable non-conducting material. The segmented non-magnetic metal element 712 is fastened to the RF coil 710 by non-conducting posts, or spacers, 719. The segmented non-magnetic metal element 712 may be formed of any number of segments, as the various aspects are not limited in this respect. In addition, according to some embodiments, the segments of the non-magnetic metal element may be interconnected by capacitors. By forming the non-magnetic metal element of segments interconnected by capacitors, eddy currents may be suppressed in the non-magnetic metal element. The capacitors interconnecting segments of a segmented non-magnetic metal element may be large value capacitors in some embodiments, for example having values on the order of microFarads, or values of approximately 100 nanoFarads, or may have any other suitable values, as the various aspects are not limited in this respect. Furthermore, the segments of the non-magnetic metal element 712 may be fixed in space by any suitable mechanism (e.g., non-conducting spacers).

FIG. 7B further illustrates the structure 700 of FIG. 7A, providing a frontal view of the structure. As shown, segmented conductor 713 comprises twelve segments. The segmented conductor 713 may have any suitable inner and outer diameters, which may be, for example, approximately 9.25 inches and 10.75 inches, respectively.

The segmented non-magnetic metal element 712 is shown as including twelve segments, each approximately triangular in shape. Therefore, the perimeter 714 of the non-magnetic metal element 712 is not a smooth curve, but rather is formed of twelve approximately straight sides. However, it should be appreciated that any suitable number and shaping of segments may be used to form the non-magnetic metal element 712, as the various aspects of the invention are not limited in this respect. For example, the perimeter 714 may form a substantially smooth curve in some embodiments, or may take any suitable shape. Moreover, the segments need not be triangular, but may take any suitable shape, and need not all be the same size and/or shape.

As shown, the segments of the non-magnetic metal element 712 are arranged such that the non-magnetic metal element has a hole 716 at its center. The hole 716 may facilitate fastening of the non-magnetic metal element to a support structure, for example by accommodating a screw, as described further below, or other fastening mechanism. It should be appreciated that the hole 716 is optional and may not be present in all embodiments.

FIG. 7C shows an RF coil configuration 701 comprising two RF coils, each of which is like the RF coil shown in FIGS. 7A-7B. The two RF coils each are mounted on a non-conducting support 752a and 752b, respectively, which are separated by 6.5 inches. The non-conducting supports are mounted to respective segmented non-magnetic metal elements, 754a and 754b, by non-conducting posts 756. In this non-limiting example, each of the non-magnetic metal elements has a diameter of approximately 12.7 inches. A plurality of capacitors 758 is included on each of the non-magnetic metal elements, the capacitors interconnecting the segments of the non-magnetic metal elements and providing capacitive coupling between the segments. The number and spacing of the capacitors 758 is not limiting, as any number of spacers may be used and they may be positioned with any suitable spacing.

As shown, the segments of the non-magnetic metal elements 754a and 754b may be curved. In the non-limiting example of FIG. 7C, the segments each have a substantially spherical curvature, although other types and degrees of curvature are possible. As shown, the non-magnetic metal element 754b has a focal point FP located approximately 13.5 inches from the non-conducting support 752b, approximately 16 inches from the apex of the non-magnetic metal element 754b, and therefore behind the non-magnetic metal element 754a. It should be appreciated that the values of the dimensions and other parameters given in FIG. 7C are merely for purposes of providing an example, as various dimensions may be used in alternative embodiments.

As mentioned in relation to FIGS. 7A-7B, according to some aspects the shape (e.g., curvature) of a non-magnetic metal element may be adjustable. For example, it may be desirable to use a non-magnetic metal element having one amount of curvature for a first application (e.g., imaging a first patient) and then use a non-magnetic metal element having a different amount of curvature for a second application (e.g., imaging a second patient). By providing a non-magnetic metal element having a variable amount of curvature, it may be unnecessary to use different non-magnetic metal elements for the two applications. Also, it may be desirable to be able to adjust a distance of separation between a non-magnetic metal element and an RF coil.

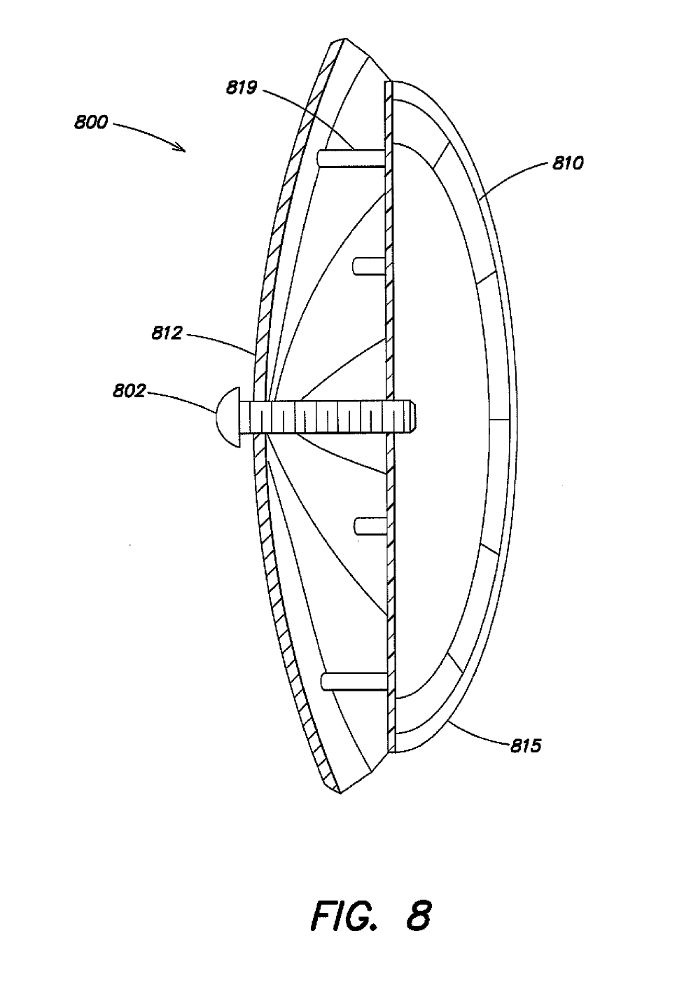

FIG. 8 illustrates a cut-away side view of an RF coil combined with a non-magnetic metal element according to one embodiment, in which a screw is provided to adjust the curvature of the non-magnetic metal element and/or the separation distance between the non-magnetic metal element and an RF coil. The structure 800 includes an RF coil 810 mounted on a non-conducting support 815. The non-conducting support 815 is fastened to a non-magnetic metal element 812 by a plurality of non-conducting posts 819. A screw 802 is provided and may be threaded through a hole in the non-magnetic metal element 812 as well as a hole in the non-conducting support 815. Thus, by loosening or tightening the screw 802, the curvature of the non-magnetic metal element 812 may be adjusted, and/or the distance of separation between the non-magnetic metal element 812 and the RF coil 810 may be adjusted. To facilitate adjusting the distance of separation between the non-magnetic metal element 812 and the RF coil 810, the posts 819 may have adjustable lengths. It should be appreciated that other methods and mechanisms for adjusting the curvature and/or separation distance of a non-magnetic metal element are also possible, and that FIG. 8 merely provides one non-limiting example of using a screw as an adjustment mechanism.

Having described several embodiments of various aspects of the invention in detail, various modifications and improvements will readily occur to those skilled in the art. Such modifications and improvements are intended to be within the spirit and scope of the various aspects of the invention. Accordingly, the foregoing description is by way of example only, and is not intended as limiting. The invention is limited only as defined by the following claims and the equivalents thereto.

For example, various embodiments of RF coils have been shown and described, and it should be appreciated that the conductors used for the RF coils may vary in several respects. For example, the conductors of the RF coils may be formed of microstrips (i.e., relatively flat strips of metal), conventional wiring, conducting tubes, or any other suitable type of conductor. Additionally, the conductor material may be copper, aluminum, an alloy, or any other suitable conducting material, and may include gold coatings, silver coatings, or any other type of coating according to some embodiments. Similarly, if the non-magnetic elements described herein are formed of a metal, they may be formed of a pure metal, an alloy, or any other suitable metal material, such as being formed of copper, gold, or aluminum, for example.

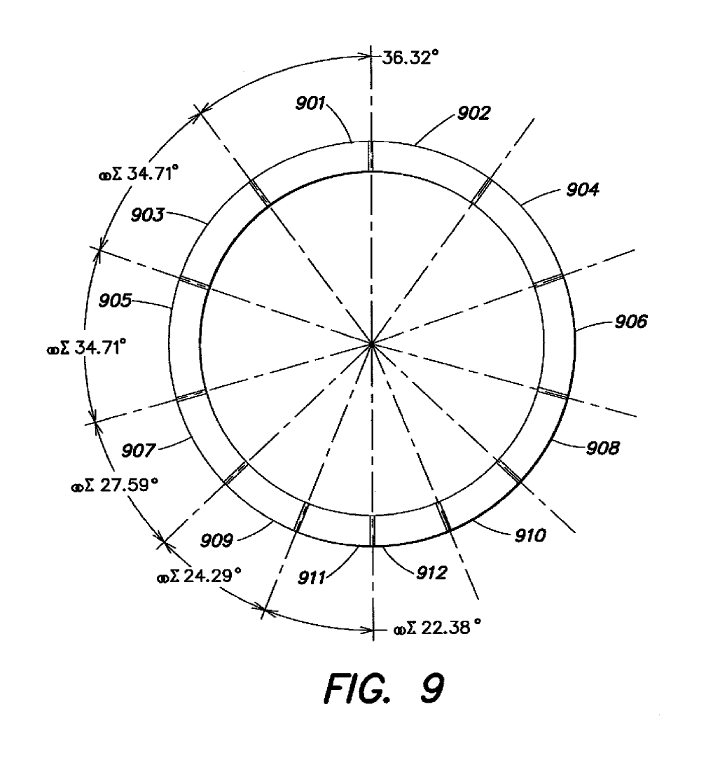

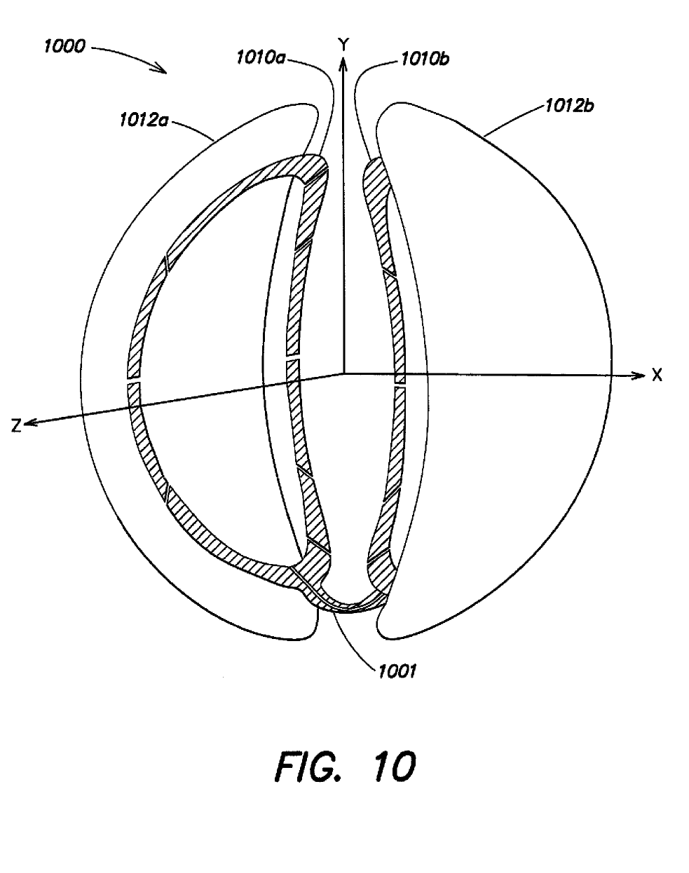

Moreover, the conductor of an RF coil according to various aspects of the invention may or may not be segmented. For example, FIGS. 2A-2B and FIGS. 7A-7B illustrate segmented conductors. However, according to some embodiments, the conductor of an RF coil is not segmented. Moreover, the number and sizing of the segments is not limiting, as any suitable number and sizing of segments may be used. In addition, according to some embodiments, a segmented conductor having non-uniform segments may be used to form an RF coil. FIG. 9 provides an illustration.

As shown in FIG. 9, a segmented conductor may be formed of twelve segments. The segments are not uniform in length. For example, the segments 901 and 902 may each span approximately 36 degrees. Segments 903 and 904 may each span approximately 35 degrees. Segments 905 and 906 may each span approximately 35 degrees. Segments 907 and 908 may each span approximately 28 degrees. Segments 909 and 910 may each span approximately 25 degrees, and segments 911 and 912 may each span approximately 22 degrees. The sizing of the segments may be chosen to provide desired operating characteristics of the RF coils. For example, using the segment size pattern illustrated in FIG. 9 for the RF coils in FIG. 2A may provide greater magnetic field uniformity than that shown and described in relation to FIG. 6. In particular, as previously discussed, FIG. 6 shows a magnetic field variation within the ROI of approximately 8.05%, as calculated using Eq. (1). Utilizing the same simulation parameters in conjunction with the conductor segment sizing of FIG. 9 may reduce the magnetic field variation within the ROI to approximately 3.18% at 300 MHz. It should be appreciated that according to some embodiments, capacitors may be inserted between the segments of the segmented conductor, such as the segmented conductor of FIG. 9, to provide electrical connection between the segments and/or to facilitate tuning.

Also, according to some aspects non-uniform capacitors are inserted between segments of a segmented conductor for an RF coil. For example, referring to FIG. 2A, the capacitors 217 may have differing values in some embodiments. According to other embodiments, all of the capacitors 217 may be identical. According to some embodiments, a conductor of an RF coil may be segmented, with segments of differing lengths, such as those shown in FIG. 9. Capacitors may be inserted between the segments of differing lengths, with two or more of the capacitors having differing values.

Also, the shapes illustrated for the various RF coils and non-magnetic metal elements are not limiting. According to some embodiments, the RF coil conductors and/or the non-magnetic metal elements may be substantially circular, rectangular, square, triangular, elliptical, have an irregular shape, or take any other suitable shape, as the various aspects of the invention are not limited in this respect. Furthermore, while some embodiments have illustrated configurations in which an RF coil and a corresponding non-magnetic metal element may have the same shape (e.g., circular), the various aspects of the invention are not limited in this respect. For example, according to one embodiment an RF coil may have a substantially circular shape and a non-magnetic metal element may have an approximately square shape. Other combinations of shapes are also possible.

Furthermore, some embodiments have illustrated RF coils and/or non-magnetic metal elements that are substantially planar. However, such configurations are not limiting, as non-planar RF coils and/or non-magnetic metal elements may also be used. FIG. 10 provides an illustration of an RF coil pair combined with two non-magnetic metal elements, in which both the RF coils and the non-magnetic metal elements are non-planar. As shown, the coil configuration 1000 comprises two segmented RF coils, 1010a and 1010b. Each of the RF coils 1010a and 1010b is curved, and therefore does not lie within a single plane. The RF coils 1010a and 1010b are connected by a connector 1001 which may provide an input signal to each of the RF coils, or for example may take the form of the interconnection shown in FIG. 2B between the RF coils. The coil configuration 1000 further comprises two non-magnetic metal elements, 1012a and 1012b. Each of the non-magnetic metal elements is curved, with one non-magnetic metal element positioned proximate each of the RF coils. It should be appreciated that the shaping and non-planar nature of the RF coils and non-magnetic metal elements in FIG. 10 are not limiting, but merely provide one example.

Various apparatus and methods have been described thus far. These apparatus and methods may be used in various contexts, such as in MRI or other contexts. For example, in the context of MRI, RF coil configurations and techniques such as those described herein may provide improved imaging capabilities of various test subjects including, but not limited to, humans and animals. The magnetic lensing techniques described herein may offer improved imaging capabilities, for example in the non-limiting context of MRI. For example, the magnetic lensing techniques may facilitate accurate definition and monitoring of regions of interest, such as feet, arms, portions of the brain, the prostate, or any other regions of interest in human or animal applications. Also, the benefits of the coil configurations and methods described herein may be achieved without secondary RF coils, e.g., a second set of Helmholtz coils around those already shown in FIG. 1A. Thus, at least some of the designs and techniques described herein may offer simplicity over conventional systems.

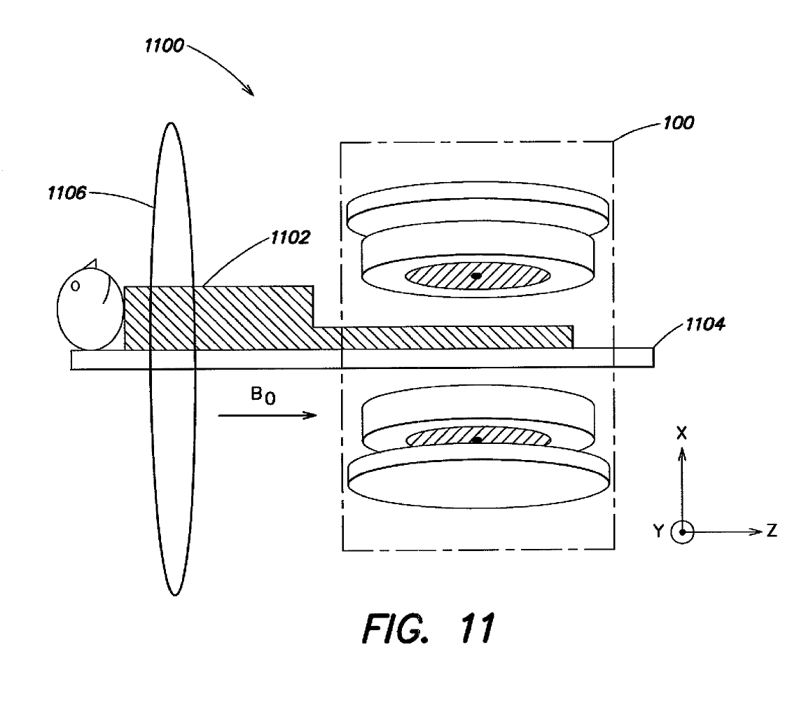

FIG. 11 provides one example of a context in which some of the designs and techniques described herein may be employed. The system 1100 is a simplified MRI system, and may be used to image a patient 1102, which may be a person, an animal, or any other type of test subject. The patient 1102 may be placed on a table 1104 within a magnetic coil 1106 (e.g., an MRI bore). The magnetic coil 1106 may generate a magnetic field Bₒ along the length of the patient 1102, i.e., in the z-direction. An RF coil configuration, such as coil configuration 100 of FIG. 1, may be positioned to allow for RF imaging of the patient 1102, for example being oriented perpendicularly to the direction of the Bₒ magnetic field. For example, the RF coil configuration may be oriented in the x-direction, as shown, or the y-direction, as two non-limiting examples. According to some embodiments, the RF coils of the coil configuration 100 may each operate as both transmit and receive RF coils, although they are not limited in this respect. For example, both RF coils of the coil configuration 100 may operate as receive coils, or one of the RF coils may operate as a transmit coil and the other as a receive coil. Other modes of operation are also possible.

While FIG. 11 provides one example of a system 1100 which may be used for MRI imaging, it should be appreciated that other systems are possible. For example, the non-limiting embodiment of FIG. 11 employs the coil configuration 100 of FIG. 1 as the RF coils for the system 1100. However, any of the coil configurations described herein may be used, and the coil configuration 100 is merely one non-limiting example.

In addition, it should also be appreciated that aspects of the invention described herein may be applied in contexts other than imaging. For example, the magnetic lensing techniques described herein may allow a suitably configured RF coil to function as a magnetic probe for directing drugs to targeted areas within a patient, or may be used in other contexts in which magnetic lensing may be desirable. Thus, the designs and techniques described herein are not limited to use with MRI or any other type of imaging.

Also, some aspects of the invention have been described as applying to a Helmholtz coil configuration, involving two RF coils of equal radii spaced by a distance approximately equal to their radii. Such a configuration is merely one non-limiting example, as aspects of the invention may also apply to coil configurations including only a single RF coil, or to arrays of RF coils comprising two or more RF coils. Furthermore, various aspects of the invention may apply to RF coils used for different purposes, such as for RF coils used as transmit RF coils, coils used as receive RF coils, and/or coils used as both transmit and receive RF coils.

1. An apparatus, comprising:
a radio frequency (RF) coil; and
a non-magnetic metal element electromagnetically coupable to the RF coil to do at least one of form a resonant system with the RF coil, focus a magnetic field produced by the RF coil, and increase a sensitivity of detection of the RF coil.

2. The apparatus of claim 1, wherein the non-magnetic metal element is electromagnetically coupable to the RF coil to form a resonant system with the RF coil.

3. The apparatus of claim 1, wherein the non-magnetic metal element is electromagnetically coupable to the RF coil to focus a magnetic field produced by the RF coil.

4. The apparatus of claim 1, wherein the non-magnetic metal element is electromagnetically coupable to the RF coil to increase a sensitivity of detection of the RF coil.

5. The apparatus of claim 4, wherein the non-magnetic metal element is electromagnetically coupled to the RF coil when the RF coil is excited by an external magnetic field.

6. The apparatus of claim 1, wherein the non-magnetic metal element is concave toward the RF coil.

7. The apparatus of claim 1, wherein the RF coil is configured to receive an input signal having a frequency within a range of ±3% of at least one of 126 MHz, 300 MHz, 400 MHz, and 500 MHz.

8. The apparatus of claim 1, wherein the non-magnetic metal element is physically coupled to the RF coil by at least one non-conducting spacer.

9. The apparatus of claim 1, wherein the RF coil defines a central point about which the RF coil is symmetric, and wherein the non-magnetic metal element is disposed on a first side of the RF coil and is symmetric about the central point.

10. The apparatus of claim 9, wherein the non-magnetic metal element is substantially flat.

11. The apparatus of claim 9, wherein the RF coil defines a first plane, and wherein the non-magnetic metal element has a perimeter defining a second plane, the second plane being substantially parallel to the first plane.

12. The apparatus of claim 11, wherein the non-magnetic metal element is concave toward the RF coil.

13. The apparatus of claim 12, wherein the non-magnetic metal element has an inner surface proximate the RF coil, and wherein the inner surface has an approximately spherical curvature.

14. The apparatus of claim 12, wherein the non-magnetic metal element has an inner surface proximate the RF coil, the inner surface being deflected from the second plane by a deflection amount, and wherein the deflection amount is variable.

15. The apparatus of claim 14, wherein the non-magnetic metal element has a hole at its center, and wherein the apparatus further comprises a positioning mechanism passing through the hole and configured to vary the deflection amount.

16. The apparatus of claim 15, wherein the positioning mechanism comprises a screw, and wherein the deflection amount is varied by tightening and/or loosening the screw.

17. The apparatus of claim 9, wherein the non-magnetic metal element is formed of a single piece of non-magnetic metal.

18. The apparatus of claim 9, wherein the non-magnetic metal element is formed of at least two pieces of non-magnetic metal.

19. The apparatus of claim 18, further comprising at least one capacitor interconnecting the at least two pieces of non-magnetic metal of the non-magnetic metal element.

20. The apparatus of claim 9, wherein the non-magnetic metal element comprises copper.

21. The apparatus of claim 9, wherein the non-magnetic metal element is a disc.

22. The apparatus of claim 9, wherein the non-magnetic metal element has an elliptical perimeter.

23. The apparatus of claim 9, wherein the RF coil is formed of segmented microstrips.

24. The apparatus of claim 9, wherein the RF coil has an inner edge proximate the central point, an outer edge distal the central point, and a first radius equal to a distance from the central point to the outer edge, and wherein the non-magnetic metal element has a second radius greater than or equal to the first radius.

25. The apparatus of claim 1, wherein the non-magnetic metal element comprises copper.

26. The apparatus of claim 1, wherein the RF coil is a first RF coil, and wherein the apparatus fixer comprises a second RF coil electromagnetically coupable to the first RF coil.

27. The apparatus of claim 26, wherein the non-magnetic metal element is a first non-magnetic metal element, and wherein the apparatus firer comprises a second non-magnetic metal element electromagnetically coupable to the second RF coil.

28. The apparatus of claim 27, wherein the first RF coil and the second RF coil form a Helmholtz pair.

29. The apparatus of claim 1, wherein the RF coil comprises a segmented conductor.

30. The apparatus of claim 29, wherein the segmented conductor comprises a plurality of segments, and wherein at least two segments of the plurality of segments have unequal lengths.

31. The apparatus of claim 29, wherein the segmented conductor comprises a plurality of segments, and wherein the apparatus further comprises a capacitor interconnecting at least two segments of the plurality of segments.

32. The apparatus of claim 31, wherein the apparatus further comprises a plurality of capacitors including the capacitor interconnecting at least two segments of the plurality of segments, each of the plurality of capacitors interconnecting at least two segments of the plurality of segments, and wherein at least two capacitors of the plurality of capacitors have different capacitive values.

33. The apparatus of claim 29, wherein the segmented conductor comprises between three and twenty segments.

34. The apparatus of claim 1, further comprising a positioning mechanism configured to adjust a distance of separation between the RF coil and the non-magnetic metal element.

35-84. (canceled)
